(19) United States
(12) Patent Application Publication
(10) Pub. No.: US 2024/0418799 A1
(43) Pub. Date: Dec. 19, 2024

(54) Detection of a crossed connection on a single-phase meter

(71) Applicant: SAGEMCOM ENERGY & TELECOM SAS, BOIS-COLOMBES (FR)

(72) Inventors: Sylvestre ADAM, BOIS-COLOMBES (FR); Pierre LHUILLIER, BOIS-COLOMBES (FR)

(21) Appl. No.: 18/744,019

(22) Filed: Jun. 14, 2024

(30) Foreign Application Priority Data
Jun. 16, 2023 (FR) FR2306208

(51) Int. Cl. G01R 31/67; G01R 22/10; G01R 25/00

(52) U.S. Cl. CPC G01R 31/67; G01R 22/10; G01R 25/00

(57) ABSTRACT

A single-phase electric meter includes a phase conductor intended to be connected to the phase; an electrical ground, which is connected to the phase conductor, a floating potential target; a processing unit arranged to measure a target voltage between the target and the phase conductor, and to detect according to the target voltage, a state of a connection of the phase and of the neutral on the meter, the state of the connection being able to be a normal connection or a crossed connection.

### DESCRIPTION

The invention relates to the field of single-phase electric meters.

### BACKGROUND OF THE INVENTION

A single-phase electric meter is intended to measure consumption, by an installation, of an electrical energy supplied to the installation by a distribution network comprising a phase and a neutral.

It can occur, that at the time of installing the meter, the operator responsible for the installation, unintentionally crosses the connection of the phase and of the neutral on the meter. In this case, the neutral of the distribution network is connected to the upstream phase terminal of the meter, and the phase of the distribution network is connected to the upstream neutral terminal of the meter.

Yet, this crossed connection represents a danger for the user (subscriber), who expects that the neutral carries little danger, and who could consequently handle the neutral of their installation without knowing, that in reality, it is connected to the phase of the network.

This can also be a potential vector for fraud, as in case of crossed connexion, it becomes possible to consume energy not measured by the meter, by connecting equipment between the neutral and the earth.

It therefore seems particularly interesting to be capable of automatically detecting a crossed connection fault, on a single-phase electric meter, between the phase and the neutral.

However, today there is no effective method for detecting such a fault on single-phase meters.

In three-phase meters, detecting a crossed connection is done by checking a simple criterion on voltage imbalances. However, such a criterion cannot be applied to a single-phase meter.

### AIM OF THE INVENTION

The invention aims to effectively detect a crossed connection between the phase and the neutral on a single-phase electric meter.

### SUMMARY OF THE INVENTION

In view of achieving this aim, a single-phase electric meter is proposed, intended to measure a consumption by an installation of an electrical energy supplied by a distribution network comprising a phase and a neutral, the meter comprising:
a phase conductor intended to be connected to the phase;
an electrical ground, which is connected to the phase conductor;
a floating potential target;
a processing unit arranged to measure a target voltage between the target and the phase conductor, and to detect, according to the target voltage, a state of a connection of the phase and of the neutral on the meter, the state of the connection being able to be a normal connection or a crossed connection.

When the connection has been made correctly, the phase of the network is connected to the phase conductor, and the target voltage is relatively high. On the contrary, when the connection has been made incorrectly, it is the neutral of the network which is connected to the phase conductor, and the target voltage is relatively low.

The integration in the meter of the floating potential target therefore makes it possible to define this target voltage, the value of which makes it possible to detect the state of the connection of the phase and of the neutral on the meter. This detection, done indirectly by way of a capacitive coupling, is very effective.

The invention is moreover, very simple and very inexpensive to implement, since it simply requires to integrate the target in the meter.

In addition, a single-phase electric meter such as described above is proposed, wherein the processing unit is arranged to compare the target voltage with a predetermined threshold, and to detect the crossed connection when the target voltage is less than said predetermined threshold.

In addition, a single-phase electric meter such as described above is proposed, wherein the target is a conductive surface formed on an electrical board and not connected to a ground plane of said electrical board.

In addition, a single-phase electric meter such as described above is proposed, wherein the processing unit comprises measuring components, arranged to measure the target voltage, which are mounted on said electrical board.

In addition, a single-phase electric meter such as described above is proposed, the processing unit being arranged to detect a presence of an individual in the proximity of the meter, and to perform the detection of the state of the connection when the individual is located in the proximity of the meter.

In addition, a single-phase electric meter such as described above is proposed, wherein the meter comprises a casing comprising a button, the processing unit being arranged to detect the presence of the individual in the proximity of the meter when it detects a press on of the button.

In addition, a single-phase electric meter such as described above is proposed, wherein the meter comprises a casing comprising a test surface located on an external surface of the casing, the processing unit being arranged to:
acquire information, according to which a procedure for manually checking the connection is started, said procedure comprising the step of positioning a hand or a finger of the individual on the test surface;
deduce from this information, that the individual is located in the proximity of the meter.

In addition, a single-phase electric meter such as described above is proposed, the processing unit being arranged to perform the detection of the state of the connection each time the meter is switched on.

In addition, a detection method is proposed, implemented in the processing unit of a single-phase electric meter such as described above, and comprising the steps of:
measuring a target voltage between the target and the phase conductor;
detecting, according to the target voltage, a state of a connection of the phase and of the neutral on the meter, the state of the connection being able to be a normal connection or a crossed connection.

In addition, a detection method such as described above is proposed, implemented in the processing unit of a single-phase electric meter such as described above, comprising the step of detecting a presence of an individual in the proximity of the meter, and of performing the detection of the state of the connection when the individual is located in the proximity of the meter.

In addition, a detection method such as described above is proposed, wherein the detection of the state of the connection comprises the steps of:
if the target voltage remains greater than a predetermined threshold for a first predetermined duration, detecting a normal connection;
if the target voltage remains less than a predetermined threshold for a second predetermined duration, detecting a crossed connection.

In addition, a detection method such as described above is proposed, implemented in the processing unit of a single-phase electric meter such as described above, comprising the step of performing the detection of the state of the connection each time the meter is switched on.

In addition, a detection method such as described above is proposed, comprising the steps of:
if the target voltage remains greater than a predetermined threshold for a third predetermined duration, detecting a normal connection;
if the target voltage remains less than the predetermined threshold for a fourth predetermined duration, detecting a crossed connection.

In addition, a computer program is proposed, comprising instructions which lead to the processing unit of the meter such as described above, executing the steps of the detection method such as described above.

In addition, a computer-readable recording medium is proposed, on which the computer program such as described above is stored.

The invention will be best understood in the light of the following description of particular non-limiting embodiments of the invention.

### BRIEF DESCRIPTION OF THE DRAWINGS

Reference will be made to the accompanying drawings, among which:

FIG. 1 represents a distribution network and a single-phase electric meter, when the phase and the neutral are correctly connected on the meter;

FIG. 2 is a figure similar to FIG. 1, when the phase and the neutral are crossed;

FIG. 3 represents steps of a detection method according to a first embodiment;

FIG. 4 represents steps of the detection method according to a second embodiment.

### DETAILED DESCRIPTION OF THE INVENTION

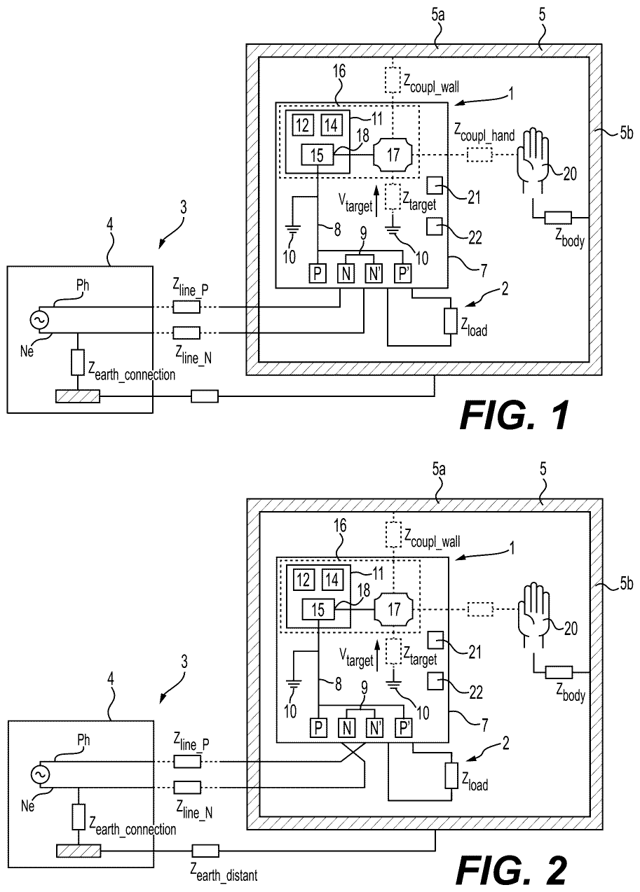

In reference to FIGS. 1 and 2, the single-phase electric meter 1 is intended to measure the electrical energy consumption of the installation 2 of a user (subscriber). The electrical energy is supplied to the installation 2 by a distribution network 3.

The distribution network 3 is a single-phase network and comprises a phase Ph and a neutral Ne.

The distribution of energy is performed equally according to the TT or TN system.

In this case, the network 3 comprises a distribution station 4 to which the installation 2 and the meter 1 are connected via the phase Ph and the neutral Ne. The distribution station 4 is a MT/BT transformation station.

The voltage supplied is, in this case, an alternating voltage with an effective voltage of 230V.

The installation 2 of the user and the meter 1 are positioned in the dwelling of the user and therefore, in a space delimited by walls 5. The installation 2 is, in this case, symbolised electrically by an impedance Z_{charge}.

The meter 1 comprises a casing 7 which comprises an upstream phase terminal P, a upstream neutral terminal N, a downstream phase terminal P′ and a downstream neutral terminal N′. In this case, by “upstream”, this means the side of the network 3, and by “downstream”, this means the side of the installation 2.

The meter 1 comprises a phase conductor 8 and a neutral conductor 9.

The phase conductor 8 is connected to the upstream phase terminal P and therefore, to the phase Ph of the distribution network 3 upstream of the meter 1. The neutral conductor 9 is connected to the upstream neutral terminal N and therefore, to the neutral Ne of the distribution network 3 upstream of the meter 1. The downstream phase terminal P′ and the downstream neutral terminal N′ are connected to the installation 2.

The phase conductor 8 is connected to an electrical ground 10 of the meter 1.

The meter 1 comprises, in addition, a processing unit 11.

The processing unit 11 comprises at least one processing component 12, which is for example, a “general-purpose” processor, a processor specialising in signal processing (or DSP, Digital Signal Processor), a microcontroller, or a programmable logic circuit, such as an FPGA (Field-Programmable Gate Array) or an ASIC (Application-Specific Integrated Circuit). The processing component 12 is, in this case, a microcontroller.

The processing unit 11 comprises, in addition, one or more memories 14, connected to or integrated in the microcontroller 12. At least one of these memories 14 forms a computer-readable recording medium, on which is recorded at least one computer program comprising instructions which lead the microcontroller 12 to execute at least some of the steps of the detection method which will be described below.

The processing unit 11 comprises, in addition, measuring components. The measuring components comprise an analogue-to-digital converter (ADC) 15 which produces digital measurements of a voltage representative of the voltage present on the phase Ph, of a voltage representative of the voltage present on the neutral Ne, and of a voltage representative of the current circulating on the phase Ph. These measurements are conventionally used by the meter 1 to evaluate the electrical consumption of the installation 2 (metrology).

The components of the processing unit 11 are, in this case, mounted on one same electrical board.

The voltage reference of the ADC 15 is the ground plane of the electrical board 16. The mass plane is connected to the electrical ground 10 and therefore, to the upstream phase terminal P.

The meter 1 comprises, in addition, a floating potential target 17, i.e. a conductive element, which is not connected to any element having a fixed potential.

The ADC 15 comprises an input 18 connected to the target 17. The ADC 15 therefore, also produces measurements of the potential difference between the target 17 and the electrical ground 10 and therefore, between the target 17 and the upstream phase terminal P of the meter 1.

The microcontroller 12 acquires and analyses the digital measurements produced by the ADC 15.

In FIG. 1, the connection of the meter 1 has been done correctly by the operator: the phase Ph of the network 3 is connected to the upstream phase terminal P of the meter 1 (and therefore, to the phase conductor 8), and the neutral Ne of the network 3 is connected to the upstream neutral terminal N of the meter 1 (and therefore, to the neutral conductor 9).

However, in FIG. 2, the operator has performed a crossed connection: the phase Ph of the network 3 is connected to the upstream neutral terminal N of the meter 1 (and therefore, to the neutral conductor 9), and the neutral Ne of the network 3 is connected to the upstream phase terminal P of the meter 1 (and therefore, to the phase conductor 8).

The invention aims to detect the state of the connection of the phase Ph and of the neutral Ne on the meter 1: the state of the connection can be a normal connection or a crossed connection.

The principle of the invention is described.

The impedance Z_{target} between the target 17 and the ground plane of the board 16 is, by construction such as proposed, high. This impedance is mainly constituted by the parasitic capacitance between the target 17 and the ground plane, typically of the order of pF, and by the input impedance of the measuring components, typically of the order of Mohm.

It is seen that the target 17 is coupled to the earth by a first capacitive coupling (permanently) and possibly, punctually, by a second capacitive coupling.

The first coupling is a fixed environment coupling, i.e. in this case, via one of the walls 5a.

The second coupling is a coupling via an individual (typically the operator or the user) positioned in the proximity of the meter 1, said individual being itself coupled to the earth by the fixed environment, i.e. in this case via the floor and one of the walls 5b.

It is assumed that the individual has approached the meter 1 with their hand 20, or even has placed their hand 20 or a finger on the meter 1.

This gives:

Z_{coupl_earth}=Z_{coupl_wall}//(Z_{coupl_hand}+Z_{body}),

Where:
Z_{coupl_earth} is the resulting coupling impedance between the target 17 and the earth;
Z_{coupl_wall} is the coupling impedance between the target 17 and the earth via the wall 5a (first coupling);
Z_{coupl_hand} is the coupling impedance between the target 17 and the hand 20 of the individual (second coupling);
Z_{body} is the coupling impedance between the body of the individual and the earth via the wall 5b and the floor (second coupling).

Naturally, if no individual is positioned in the proximity of the meter 1, the target 17 is coupled to the earth via the wall 5a only, and:

Z_{coupl_earth}=Z_{coupl_wall}

The earth impedance Zₑₐᵣₜₕ distant, i.e. the impedance between the local earth of the meter 1 and the earth at the network voltage source (distribution station 4) is low (typically <100 ohms).

The fixed environment diversities will make the first coupling very variable (and sometimes very low). However, the second coupling will always be significant when an individual is close to the meter 1. This proximity of the body of the individual can be made, for example, by their hand: involuntarily during the use of the buttons 21 of the meter 1, or voluntarily by placing it on a surface 22 of the casing 7 of the meter 1 provided for this purpose, during an explicit detection phase.

When the cabling is done correctly, as is the case in FIG. 1, the target voltage V_{target}, which is established between the target 17 and the ground plane (and therefore, the phase conductor 8), is given by:

V_{target}=V_{network}×Z_{target}/(Z_{target}+Z_{coupl_earth}+Z_{earth_distant}+Z_{earth_connection}+(Z_{line_P}//(Z_{line_N}+Z_{charge})))

We have:

Z_{earth_distant}+Z_{earth_connection}+Z_{line_P}<<Z_{coupl_earth}

Z_{earth_distant}+Z_{earth_connection}+Z_{line_P}<<Z_{target}

Z_{lineP}<<Z_{charge}

The equation above can therefore, be rewritten in the following simplified manner:

V_{target}=V_{network}×Z_{target}/(Z_{target}+Z_{coupl_earth})

It is observed that, when the cabling is correctly done, a significant voltage is then established on the target 17, as Z_{target} is of an order of magnitude greater than or similar to Z_{coupl_earth}.

The target 17 is located inside the casing 7, since the principle of detection is done contactless.

The target 17 is, in this case, a conductive surface (range) formed on the electrical board 16 and not connected to the ground plane of said electrical board 16.

The target 17 is, for example, a square conductive surface of 5 mm×5 mm.

With the coupling being assumed linear, the target voltage must therefore, be a sinusoid of the same frequency, and the amplitude dependent on the force of the target-earth coupling. For this amplitude to be relatively high and therefore, easily measurable, it is preferable that the impedance of the target-earth coupling (through the fixed environment or through the hand of the user), be of an order of magnitude similar or greater than the target-phase impedance (typically constituted by the input impedance of the ADC 15 and by the parasitic coupling between the target 17 and the ground plane of the meter 1 which is connected to its upstream phase terminal P).

In the case of crossed connection, illustrated in FIG. 2, the target voltage V_{target} tends to be zero. Indeed, in this configuration, the target voltage V_{target} is expressed as follows:

$${V}_{t a r g e t} = [ {V}_{n e t w o r k} / ( 1 + ( {Z}_{c h a r g e} + {Z}_{l ine\_P} ) / {Z}_{line\_N} ) ] \times {Z}_{t a r g e t} / ( {Z}_{t a r g e t} + {Z}_{couple\_earth} + {Z}_{earth\_distant} + {Z}_{earth\_connection} + ( {Z}_{line\_P} // ( {Z}_{line\_N} + {Z}_{c h a r g e} ) ) )$$

And as Z_{charge}>>Z_{line_N}, the first part of this expression tends towards 0.

Thus, it is observed that the target voltage V_{target}, when the connection has been correctly made, is clearly greater than the target voltage V_{target} in the case of a crossed connection.

The processing unit 11 therefore, measures the target voltage V_{target} between the target 17 and the phase conductor 8, and detects, according to the target voltage V_{target}, the state of the connection of the phase Ph and of the neutral Ne on the meter 1. The state of the connection can be a normal connection or a crossed connection.

The processing unit 11 compares the target voltage V_{target} with a predetermined threshold, and detects the crossed connection when the target voltage V_{target} is less than said predetermined threshold. In this case, it is the amplitude of the effective value of the target voltage which is compared with the predetermined threshold.

The predetermined threshold V_{threshold} depends, in particular, on the dimensions of the target 17.

In the example of the sizing of target 17 which has been described, the predetermined threshold V_{threshold} is, for example, equal to 150 mV.

The target voltage V_{target} is, for example, an effective value (RMS, Root Mean Square voltage), calculated on an integration window of duration equal for example to 1 s.

The target voltage actually present on the target 17 and measured via the ADC 15 is an alternating voltage of frequency equal to 50 Hz (or 60 Hz).

Filtering can be implemented to filter out the noises of higher frequencies coming from disruptive sources that are susceptible to bias the measuring result (the “high impedance” nature and optionally remote from the target makes it potentially easily susceptible to noise sources).

Filtering is preferably a digital filtering. The filter used is thus, for example, a 50 Hz bandwidth digital filter of order 2.

An analogue filter can also be used.

The filter is, in this case, implemented in the processing unit 11.

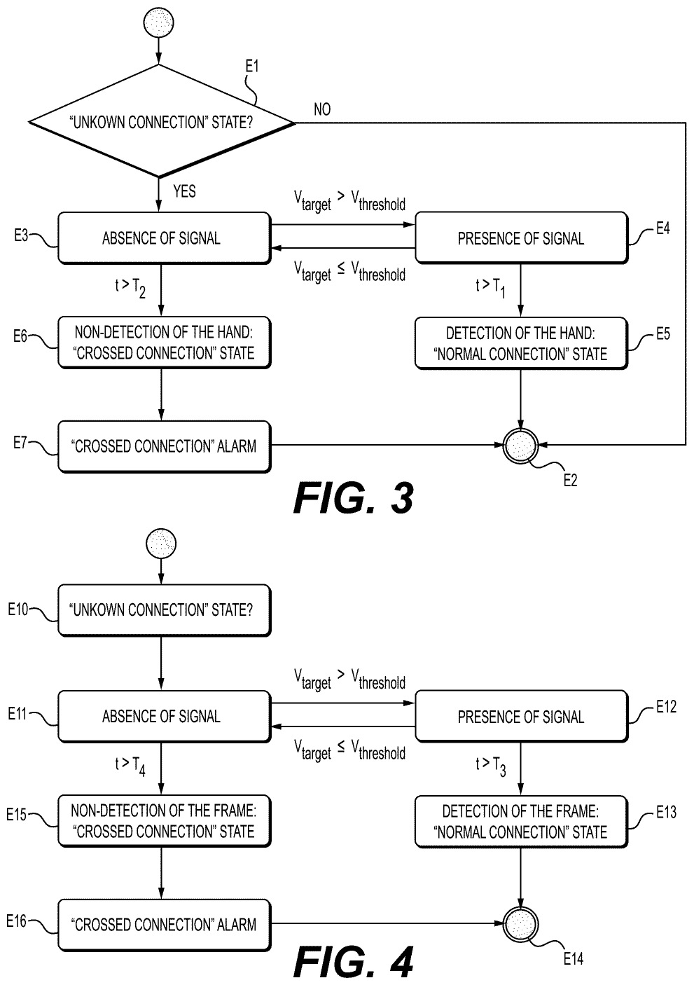

A first embodiment of the detection method is now described, in reference to FIG. 3, which is implemented in the processing unit 11.

The method therefore, consists of monitoring the target voltage V_{target}, and of performing an instantaneous detection around the instants where the coupling with the user is ensured.

In this case, measuring the target voltage is done continuously, as soon as the meter 1 is switched on. The detection of the state of the connection, i.e. the comparison with the predetermined threshold and the analysis of the result, is done each time that the processing unit 11 detects the presence of the user (or of another individual) in the proximity of the meter 1. Alternatively, measuring the target voltage V_{target} could start only when the presence of the user is detected.

The processing unit 11 can detect the presence of the user in the proximity of the meter 1 when it detects a press on the button 21. Indeed, when a press on the button 21 of the meter 1 is performed, this necessarily means that an individual is positioned in the proximity of the meter 1. The button 21 is any button of the meter 1, which is not initially dedicated to this function (but which could be).

The processing unit 11 can also use the test surface 22. This test surface makes it possible to perform a procedure for manually detecting the state of the connection. The user informs the meter 1, and the processing unit 11, when they wish to start this manual procedure. They communicate, for that, with the meter 1 via any interface: a button on the meter 1, by using their smartphone, etc. This manual procedure requires the user to position his hand or a finger on the test surface 22, which is positioned on the external surface of the casing 7, while being located in the proximity of the target 17.

The processing unit 11 therefore, acquires information, according to which a procedure for manually checking the connection is started, said procedure comprising the step of positioning a hand or a finger of the individual on the test surface 22. The processing unit 11 deduces from this information, that the individual is located in the proximity of the meter 11.

Following the detection of the presence of the individual in the proximity of the meter 1, the method starts with a starting step: step E1.

If the state of the connection is not the Unknown Connection state, the method moves to step E2, and ends.

If the state of the connection is the Unknown Connection state, the processing unit 11 analyses the target voltage V_{target}: step E3.

If this is greater than the predetermined threshold (in this case, strictly greater than), the method moves to step E4.

In step E4, if the target voltage V_{target} remains greater than the predetermined threshold for (at least) one first predetermined duration T₁, the processing unit 11 detects the hand of the user, and therefore, a normal connection on the meter 1: step E5.

The first predetermined duration T₁ is a very short (programmable) time threshold, typically equal to a few seconds.

The method thus ends: step E2.

In step E4, if the target voltage becomes less than (in this case, less than or equal to) the predetermined threshold before the end of the first predetermined duration T₁, the method returns to step E3.

In step E3, if the target voltage remains less than (in this case, less than or equal to) the predetermined threshold for (at least) a second predetermined duration T₂, the processing unit 11 does not detect the hand of the user, and therefore, detects a crossed connection: step E6.

The second predetermined duration T₂ is a very short (programmable) time threshold, typically equal to a few seconds.

The processing unit 11 thus transmits an alarm to the central system, i.e. to the energy distributor and/or to the network manager: step E7. The alarm is typically raised via a powerline communication (for example, according to protocol CPL-G3), or via a radio communication (for example, via the LTE-M network or according to protocol NB-IoT).

An alarm message, intended for the user, is also displayed on the screen of the meter 1. The operator responsible for the installation of the meter 1 can also observe his error thanks to the alarm message and correct it immediately.

The method thus ends: step E2.

Now, a second embodiment of the detection method is described, in reference to FIG. 4, which is implemented in the processing unit 11.

This embodiment consists of monitoring the target voltage V_{target}, and of seeking a long consecutive period of signal absence to detect the frame.

In this case, measuring the target voltage V_{target} and detecting the state of the connection, i.e. the comparison with the predetermined threshold, are done continuously, as soon as the meter 1 is switched on.

Given that the connection of the meter 1 is done, necessarily when switched off, the detection method is triggered each time the power is switched on to check that the cabling direction is correct during the initial installation, or that it has not been modified during the last switch-off. The initial state of the state of the connection is therefore, the Unknown state upon starting the method: step E10.

The processing unit 11 analyses the target voltage V_{target}: step E11.

If this is greater than the predetermined threshold (in this case, strictly greater than), the method moves to step E12.

In step E12, if the target voltage remains greater than the predetermined threshold for (at least) a third predetermined duration T₃, the processing unit 11 detects the frame, and therefore, a normal connection on the meter 1: step E13.

The third predetermined duration T₃ is a quite short (programmable) time threshold to avoid false positives, typically equal to ten seconds.

The method thus ends: step E14.

In step E12, if the target voltage becomes less than (in this case, less than or equal to) the predetermined threshold before the end of the third predetermined duration T₃, the method returns to step E11.

In step E11, if the target voltage remains less than (in this case, less than or equal to) the predetermined threshold for (at least) a fourth predetermined duration T₄, the processing unit 11 does not detect the frame, and therefore, detects a crossed connection: step E15.

The fourth predetermined duration T₄ is a quite long (programmable) time threshold to avoid false positives, typically equal to one hour.

The processing unit 11 thus transmits an alarm to the central system, i.e. to the energy distributor and/or to the network manager: step E16. The alarm is typically raised via a powerline communication (for example, according to protocol CPL-G3), or via a radio communication (for example, via the LTE-M network or according to protocol NB-IoT).

An alarm message, intended for the user, is also displayed on the screen of the meter 1. The operator responsible for the installation of the meter 1 can also observe his error thanks to the alarm message and correct it immediately.

The method thus ends: step E14.

Whatever the embodiment of the detection method, it is possible to predict that the method is disengageable: the energy distributor and/or the network manager and/or the user can decide to deactivate this function.

The two embodiments can naturally be combined. Thus, the detection according to the second embodiment will be implemented each time the meter 1 is switched on, and the detection according to the first embodiment will be implemented each time that the processing unit 11 detects the presence of the individual in the proximity of the meter 1.

Naturally, the invention is not limited to the embodiments described but comprises any variant entering into the field of the invention such as defined by the claims.

The target surface could be of different shape and dimensions from those mentioned in this case. It could be positioned differently in the meter (it is not positioned necessarily on an electrical board).

The target could, in particular, be moved above, below or to the side of the electrical board.

The target is for example, located at 1 cm from the ground plane of the electrical board by being raised.

The target is then for example, positioned on a mechanical part (support) provided to this end, in order to ensure that its location is well-controlled, and is connected to the electrical board (for measuring the voltage by the ADC) by a conductive wire, the size and the positioning of which are carefully ensured so that the coupling that it provides with the ground plane of the board remains negligible, or at least considered in the overall sizing.

It is noted that when the target is directly integrated on the electrical board, there is a distance with respect to the ground plane, more typically around 1 mm. If the latter case leads to too much coupling with the ground plane of the board, a “clipping” of the ground plane of the copper layers of the printed circuit can be considered, which are opposite the target, and have for example, a coupling rather than of the coplanar type.

The geometric solutions are multiple, in practice, according to the surface of the target, its positioning with respect to the ground of the electrical board (whether it is remote or not) and with respect to the external surfaces of the casing.

To further improve the target-earth coupling, it is possible to use the inside of the casing and in proximity of the target, an excess thickness of a solid material (for example, and preferably, plastic) providing a permittivity which is notably greater than air, which makes it possible to reach farther distances and/or a capacitive coupling which is greater than with one same air-filled volume.

The detection of the presence of an individual in the proximity of the meter could be done differently and in particular, thanks to any type of proximity sensor.

The architecture of the electrical board and the components used could be different. An amplification and protection stage can, for example, be integrated to the acquisition components of the target voltage, comprising for example, an operational amplifier. The components of the processing unit are not necessarily all mounted on one same electrical board.

1. A single-phase electric meter, intended to measure a consumption by an installation of an electrical energy supplied by a distribution network comprising a phase (Ph) and a neutral (Ne), the meter comprising:
a phase conductor intended to be connected to the phase;
an electrical ground, which is connected to the phase conductor;
a floating potential target;
a processing unit arranged to measure a target voltage between the target and the phase conductor, and to detect, according to the target voltage, a state of a connection of the phase and of the neutral on the meter, the state of the connection being able to be a normal connection or a crossed connection.

2. The single-phase electric meter according to claim 1, wherein the processing unit is arranged to compare the target voltage with a predetermined threshold, and to detect the crossed connection when the target voltage is less than said predetermined threshold.

3. The single-phase electric meter according to claim 1, wherein the target is a conductive surface formed on an electrical board (16) and not connected to a ground plane of said electrical board.

4. The single-phase electric meter according to claim 3, wherein the processing unit comprises measuring components, arranged to measure the target voltage, which are mounted on said electrical board.

5. The single-phase electric meter according to claim 1, the processing unit being arranged to detect a presence of an individual in the proximity of the meter, and to perform the detection of the state of the connection when the individual is located in the proximity of the meter.

6. The single-phase electric meter according to claim 5, wherein the meter comprises a casing comprising a button, the processing unit being arranged to detect the presence of the individual in the proximity of the meter when it detects a press on the button.

7. The single-phase electric meter according to claim 5, wherein the meter comprises a casing comprising a test surface located on an external surface of the casing, the processing unit being arranged to:
acquire information, according to which a procedure for manually checking the connection is started, said procedure comprising the step of positioning a hand or a finger of the individual on the test surface;
deduce from this information that the individual is located in the proximity of the meter.

8. The single-phase electric meter according to claim 1, wherein the processing unit is arranged to perform the detection of the state of the connection each time the meter is switched on.

9. A detection method, implemented in the processing unit of the single-phase electric meter according to claim 1, and comprising the steps of:
measuring a target voltage between the target and the phase conductor;
detecting, according to the target voltage, a state of a connection of the phase and of the neutral on the meter, the state of the connection being able to be a normal connection or a crossed connection.

10. The detection method according to claim 9, wherein the processing unit is arranged to detect a presence of an individual in the proximity of the meter, and to perform the detection of the state of the connection when the individual is located in the proximity of the meter wherein the detection method comprises the step of detecting a presence of an individual in the proximity of the meter, and of performing the detection of the state of the connection when the individual is located in the proximity of the meter.

11. The detection method according to claim 10, wherein the detection of the state of the connection comprises the steps of:
if the target voltage remains greater than a predetermined threshold for a first predetermined duration, detecting a normal connection;
if the target voltage remains less than the predetermined threshold for a second predetermined duration, detecting a crossed connection.

12. The detection method according to claim 9, wherein the processing unit is arranged to perform the detection of the state of the connection each time the meter is switched on, wherein the detection method comprises the step of performing the detection of the state of the connection each time the meter is switched on.

13. The detection method according to claim 12, comprising the steps of:
if the target voltage remains greater than a predetermined threshold for a third predetermined duration, detecting a normal connection;
if the target voltage remains less than the predetermined threshold for a fourth predetermined duration, detecting a crossed connection.

14. (canceled)

15. A computer-readable recording medium, on which a computer program is recorded, wherein the computer program comprises instructions which leads the processing unit of the meter according to claim 1 to execute a detection method, implemented in the processing unit of the single-phase electric meter, and comprising the steps of:
measuring a target voltage between the target and the phase conductor;
detecting, according to the target voltage, a state of a connection of the phase and of the neutral on the meter, the state of the connection being able to be a normal connection or a crossed connection.
